(19) United States
(12) Patent Application Publication
(10) Pub. No.: US 2024/0195361 A1
(43) Pub. Date: Jun. 13, 2024

(54) MILLIMETER-WAVE CLASS EF POWER AMPLIFIER WITH CONCURRENT HARMONIC AND SUBHARMONIC TUNING

(71) Applicant: UNIVERSITY OF SOUTHERN CALIFORNIA, Los Angeles, CA (US)

(72) Inventors: Shuo-Wei CHEN, Los Angeles, CA (US); Aoyang ZHANG, Los Angeles, CA (US)

(73) Assignee: UNIVERSITY OF SOUTHERN CALIFORNIA, Los Angeles, CA (US)

(21) Appl. No.: 18/288,021

(22) PCT Filed: Apr. 25, 2022
(86) PCT No.: PCT/US2022/026193

§ 371 Date: Oct. 23, 2023

Related U.S. Application Data
(60) Provisional application No. 63/179,494, filed on Apr. 25, 2021.

(51) Int. Cl. H03F 1/02; H03F 1/56; H03F 3/217

(52) U.S. Cl. CPC H03F 1/0244; H03F 1/565; H03F 3/2176; H03F 2200/451

(57) ABSTRACT

A subharmonic switching power amplifier architecture includes a power amplifier core that includes at least one power amplifier that receives an input signal and is operable in a power back-off region. Characteristically, the at least one power amplifier is configured to be toggled at a carrier frequency (Fc) when the power level of the input signal is equal to or higher than a predetermined power level and at a subharmonic component of the carrier frequency when the power level of the input signal is less than the predetermined power level. Concurrent harmonic tuning and subharmonic tuning is implemented to enhance the efficiency at both peak power mode and power back-off mode. Characteristically, the power amplifier being configured to be operated by a voltage mode or current mode driver and in the current mode with zero-voltage-switching.

### CROSS-REFERENCE TO RELATED APPLICATIONS

This application claims the benefit of U.S. provisional application Ser. No. 63/179,494 filed Apr. 25, 2021, the disclosure of which is hereby incorporated in its entirety by reference herein.

### STATEMENT REGARDING FEDERALLY SPONSORED RESEARCH OR DEVELOPMENT

The invention was made with Government support under Contract No. FA8650-19-1-7996 awarded by the Defense Advanced Research Projects Agency (DARPA). The Government has certain rights to the invention.

### TECHNICAL FIELD

In at least one aspect, the present invention relates to millimeter-wave class EF power amplifiers.

### BACKGROUND

Sensing or communication using the millimeter (mm)-wave band, such as mm-wave 5G systems and radar applications, is drawing increasing research interest. These systems typically employ an array of power amplifiers (PAs), with each PA operating at moderate output power. In this case, the power efficiency of the PA is crucial for better power and thermal management. Due to the high peak-to-average power ratios of spectrum-efficient modulations, the power back-off (PBO) efficiency is becoming increasingly important. The Class E/F switching PA is a favorable candidate at the mm-wave frequency band, as it can incorporate zero-voltage-switching (ZVS) and zero-derivative-voltage switching (ZdVS). Moreover, it reduces the I/V overlap from finite on-resistance by terminating different harmonics, leading to better peak efficiency. However, its efficiency roll-off still follows a typical Class B curve, resulting in relatively poor PBO efficiency.

Recently, a voltage-mode subharmonic switching (SHS) digital PA architecture [1-3] has been demonstrated to improve PBO efficiency by togging PA cells at the subharmonic frequency for the output PBO.

Accordingly, there is a need for improved PBO efficiency to millimeter-wave class EF power amplifiers.

### SUMMARY

In at least one aspect, a subharmonic switching power amplifier architecture includes a power amplifier core that includes at least one power amplifier that receives an input signal and is operable in a power back-off region. Characteristically, the at least one power amplifier is configured to be toggled at a carrier frequency (Fc) when the power level of the input signal is equal to or higher than a predetermined power level and at a subharmonic component of the carrier frequency when the power level of the input signal is less than the predetermined power level. Characteristically, the power amplifier is configured to be operated by a voltage mode or current mode driver and in the current mode with zero-voltage-switching.

In at least one aspect, a subharmonic switching power amplifier architecture includes a power amplifier core that includes at least one power amplifier that receives an input signal and is operable in a power back-off region. Characteristically, the at least one power amplifier is configured to be toggled at a carrier frequency (Fc) when the power level of the input signal is equal to or higher than a predetermined power level and at a subharmonic component of the carrier frequency when the power level of the input signal is less than the predetermined power level. Characteristically, the power amplifier is configured to be a Class-D power amplifier or a current mode Class-D power amplifier or a Class-E power amplifier or a Class-E/F power amplifier.

In another aspect, subharmonic switching power amplifier architecture optimizes peak and PBO efficiency with concurrent harmonic and subharmonic tuning Class E/F2,2/3 SHS PA for mm-wave operation that: 1) utilizes both harmonic and subharmonic tuning to reduce I/V overlap (i.e., conduction loss) for both peak and PBO operation and 2) allows the PA cells to toggle at a much lower frequency (i.e., subharmonic frequency) in PBO, which facilitates square switching waveform and reduces the loss of high-frequency clock routing. At the circuit level, an on-chip concurrent harmonic and subharmonic tuning matching network simultaneously provides optimal impedance of the fundamental frequency (Fc) and one or more harmonic components provided by N*Fc where N is a positive integer and/or one or more harmonic frequencies that are fractional frequency subharmonics provided by P*Fc/M where P and M are positive frequencies. The on-chip concurrent harmonic and subharmonic tuning matching network has a compact footprint without involving any tunable switches and elements.

In another aspect, an on-chip concurrent tuning matching network includes a subharmonic trap. Characteristically, the on-chip concurrent harmonic and subharmonic tuning matching network is configured to simultaneously provide optimal impedance at a carrier frequency and/or one or more harmonics and/or one or more subharmonics.

In another aspect, the subharmonic trap is a coupled-inductor-based subharmonic trap.

Advantageously, the prototype achieves 40.5% PAE at Psat and 24% PAE at −9 dB PBO. It largely enhanced deep PBO efficiency enhancement at mm-wave frequency bands.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

For a further understanding of the nature, objects, and advantages of the present disclosure, reference should be made to the following detailed description, read in conjunction with the following drawings, wherein like reference numerals denote like elements and wherein:

FIG. 1. Schematic of subharmonic switching power amplifier that utilizes concurrent harmonic and subharmonic tuning.

FIG. 2A. Schematic of a conventional 2nd harmonic tuning class E/F2 power amplifier.

FIG. 2B. Schematic of the concurrent harmonic and subharmonic tuning class E/F2,2/3 SHS PA described herein.

FIGS. 3A, 3B, 3C, 3D, and 3E. Concurrent tuning matching network.

FIG. 3A. Schematic of a portion of concurrent harmonic and subharmonic tuning architecture with amplifier core and matching network.

FIG. 3B. Schematic depicting signal-dependent operation of the component of the matching network 16.

FIG. 3C. Top view of the matching network.

FIG. 3D. H-Field map for a 10 GHz (Fc/3) excitation.

FIG. 3E. H-Field map for a 30 GHz (Fc) excitation.

FIG. 4. Block diagram of the Class E/F2,2/3 SHS PA.

FIGS. 5A, 5B, and 5C. CW measurement and small signal S-parameters.

FIG. 6. Modulation measurement results.

FIG. 7. Comparison with state-of-the-art CMOS and SiGe PAs

### DETAILED DESCRIPTION

Reference will now be made in detail to presently preferred embodiments and methods of the present invention, which constitute the best modes of practicing the invention presently known to the inventors. The Figures are not necessarily to scale. However, it is to be understood that the disclosed embodiments are merely exemplary of the invention that may be embodied in various and alternative forms. Therefore, specific details disclosed herein are not to be interpreted as limiting, but merely as a representative basis for any aspect of the invention and/or as a representative basis for teaching one skilled in the art to variously employ the present invention.

It is also to be understood that this invention is not limited to the specific embodiments and methods described below, as specific components and/or conditions may, of course, vary. Furthermore, the terminology used herein is used only for the purpose of describing particular embodiments of the present invention and is not intended to be limiting in any way.

It must also be noted that, as used in the specification and the appended claims, the singular form “a,” “an,” and “the” comprise plural referents unless the context clearly indicates otherwise. For example, reference to a component in the singular is intended to comprise a plurality of components.

The term “comprising” is synonymous with “including,” “having,” “containing,” or “characterized by.” These terms are inclusive and open-ended and do not exclude additional, unrecited elements or method steps.

The phrase “consisting of” excludes any element, step, or ingredient not specified in the claim. When this phrase appears in a clause of the body of a claim, rather than immediately following the preamble, it limits only the element set forth in that clause; other elements are not excluded from the claim as a whole.

The phrase “consisting essentially of” limits the scope of a claim to the specified materials or steps, plus those that do not materially affect the basic and novel characteristic(s) of the claimed subject matter.

With respect to the terms “comprising,” “consisting of,” and “consisting essentially of,” where one of these three terms is used herein, the presently disclosed and claimed subject matter can include the use of either of the other two terms.

It should also be appreciated that integer ranges explicitly include all intervening integers. For example, the integer range 1-10 explicitly includes 1, 2, 3, 4, 5, 6, 7, 8, 9, and 10. Similarly, the range 1 to 100 includes 1, 2, 3, 4 . . . . 97, 98, 99, 100. Similarly, when any range is called for, intervening numbers that are increments of the difference between the upper limit and the lower limit divided by 10 can be taken as alternative upper or lower limits. For example, if the range is 1.1. to 2.1 the following numbers 1.2, 1.3, 1.4, 1.5, 1.6, 1.7, 1.8, 1.9, and 2.0 can be selected as lower or upper limits.

When referring to a numerical quantity, in a refinement, the term “less than” includes a lower non-included limit that is 5 percent of the number indicated after “less than.” A lower non-includes limit means that the numerical quantity being described is greater than the value indicated as a lower non-included limited. For example, “less than 20” includes a lower non-included limit of 1 in a refinement. Therefore, this refinement of “less than 20” includes a range between 1 and 20. In another refinement, the term “less than” includes a lower non-included limit that is, in increasing order of preference, 20 percent, 10 percent, 5 percent, 1 percent, or 0 percent of the number indicated after “less than.”

For any device described herein, linear dimensions and angles can be constructed with plus or minus 50 percent of the values indicated rounded to or truncated to two significant figures of the value provided in the examples. In a refinement, linear dimensions and angles can be constructed with plus or minus 30 percent of the values indicated rounded to or truncated to two significant figures of the value provided in the examples. In another refinement, linear dimensions and angles can be constructed with plus or minus 10 percent of the values indicated rounded to or truncated to two significant figures of the value provided in the examples.

With respect to electrical devices, the term “connected to” means that the electrical components referred to as connected to are in electrical communication. In a refinement, “connected to” means that the electrical components referred to as connected to are directly wired to each other. In another refinement, “connected to” means that the electrical components communicate wirelessly or by a combination of wired and wirelessly connected components. In another refinement, “connected to” means that one or more additional electrical components are interposed between the electrical components referred to as connected to with an electrical signal from an originating component being processed (e.g., filtered, amplified, modulated, rectified, attenuated, summed, subtracted, etc.) before being received to the component connected thereto.

The term “electrical communication” means that an electrical signal is either directly or indirectly sent from an originating electronic device to a receiving electrical device. Indirect electrical communication can involve processing of the electrical signal, including but not limited to, filtering of the signal, amplification of the signal, rectification of the signal, modulation of the signal, attenuation of the signal, adding of the signal with another signal, subtracting the signal from another signal, subtracting another signal from the signal, and the like. Electrical communication can be accomplished with wired components, wirelessly connected components, or a combination thereof.

The term “one or more” means “at least one” and the term “at least one” means “one or more.” The terms “one or more” and “at least one” include “plurality” as a subset.

The term “substantially,” “generally,” or “about” may be used herein to describe disclosed or claimed embodiments. The term “substantially” may modify a value or relative characteristic disclosed or claimed in the present disclosure. In such instances, “substantially” may signify that the value or relative characteristic it modifies is within +0%, 0.1%, 0.5%, 1%, 2%, 3%, 4%, 5% or 10% of the value or relative characteristic.

The term “electrical signal” refers to the electrical output from an electronic device or the electrical input to an electronic device. The electrical signal is characterized by voltage and/or current. The electrical signal can be stationary with respect to time (e.g., a DC signal) or it can vary with respect to time.

The term “electronic component” refers is any physical entity in an electronic device or system used to affect electron states, electron flow, or the electric fields associated with the electrons. Examples of electronic components include, but are not limited to, capacitors, inductors, resistors, thyristors, diodes, transistors, etc. Electronic components can be passive or active.

The term “electronic device” or “system” refers to a physical entity formed from one or more electronic components to perform a predetermined function on an electrical signal.

The term “optimal impedance” means that the matching network provides a load input impedance that is within 30% of the load impedance that provide maximum power transfer.

It should be appreciated that in any figures for electronic devices, a series of electronic components connected by lines (e.g., wires) indicates that such electronic components are in electrical communication with each other. Moreover, when lines directed connect one electronic component to another, these electronic components can be connected to each other as defined above.

Throughout this application, where publications are referenced, the disclosures of these publications in their entireties are hereby incorporated by reference into this application to more fully describe the state of the art to which this invention pertains.

### Abbreviations

“Fc” means carrier frequency.
“PA” means power amplifier.
“PBO” means power back-off.
“PCB” means printed circuit board.
“LVDS” means low voltage differential signaling.
“RF” means radio frequency.
“SHS” means subharmonic switching.
“TIA” means transimpedance amplifier.
“ZdVS” means zero-derivative-voltage switching.
“ZVS” means zero-voltage-switching.

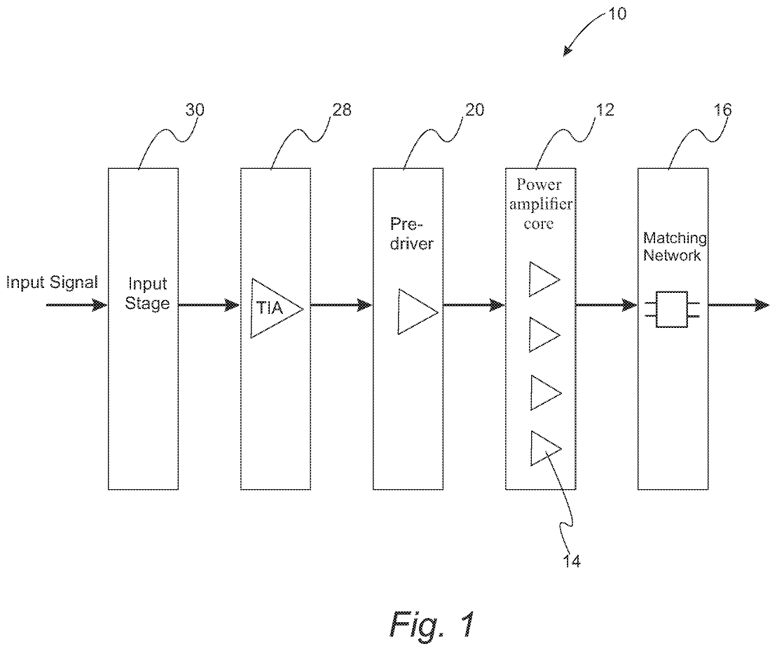

FIG. 1 provides a schematic of subharmonic switching power amplifier that utilizes concurrent harmonic and subharmonic tuning. Advantageously, subharmonic switching power amplifier architecture is configured to operate from RF to mm-Wave frequencies. In a refinement, the subharmonic switching power amplifier can operate at frequencies from 0.1 to 60 GHz. Subharmonic switching power amplifier architecture 10 includes power amplifier core 12 that includes at least one power amplifier 14 that receives an input signal and is operable in a power back-off region. Typically, power amplifier core 12 includes at least a plurality of power amplifiers 14. Characteristically, the at least one power amplifier 14 is configured to be toggled at a carrier frequency (Fc) when the power level of the input signal is equal to or higher than a predetermined power level and at a subharmonic component of the carrier frequency when the power level of the input signal is less than the predetermined power level. In a refinement, the power amplifier(s) 14 is configured to be operated by a voltage mode or current mode driver. In a further refinement, the power amplifier (s) 14 operate in the current mode with zero-voltage-switching. The power amplifier (s) 14 are typically switching amplifiers. In another refinement, the power amplifier is configured to be a Class-D power amplifier or a current mode Class-D power amplifier or a Class-E power amplifier or a Class-E/F power amplifier. Advantageously, subharmonic switching power amplifier architecture 10 is configured to reduce conduction loss and minimize output impedance variation by toggling a plurality of power amplifier branches.

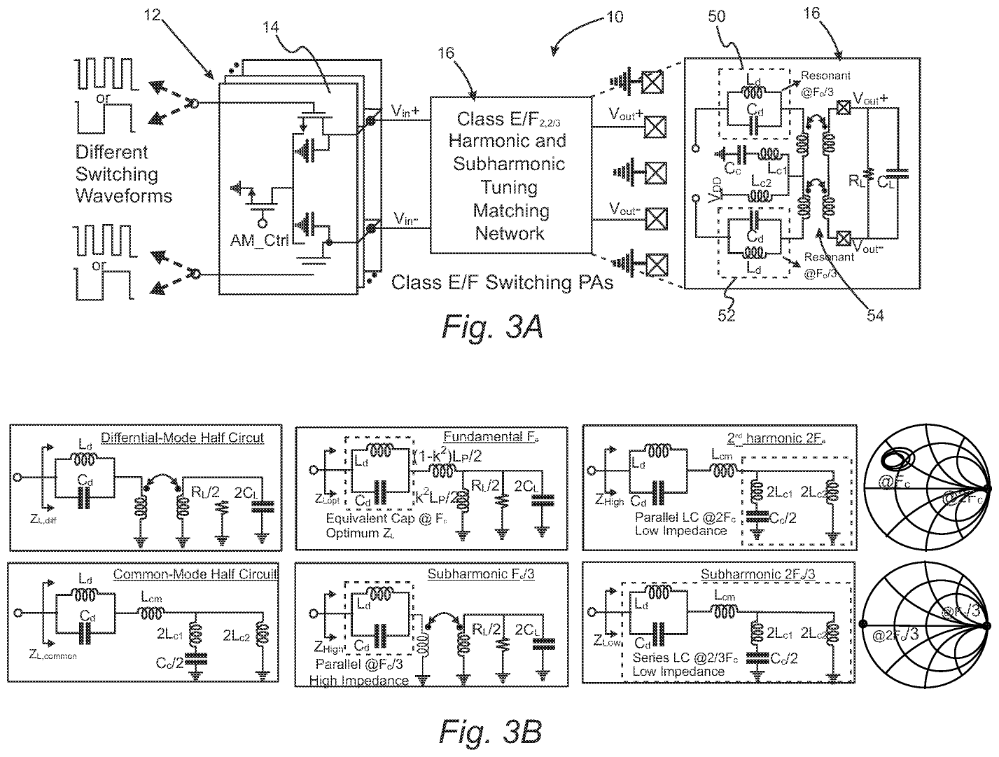

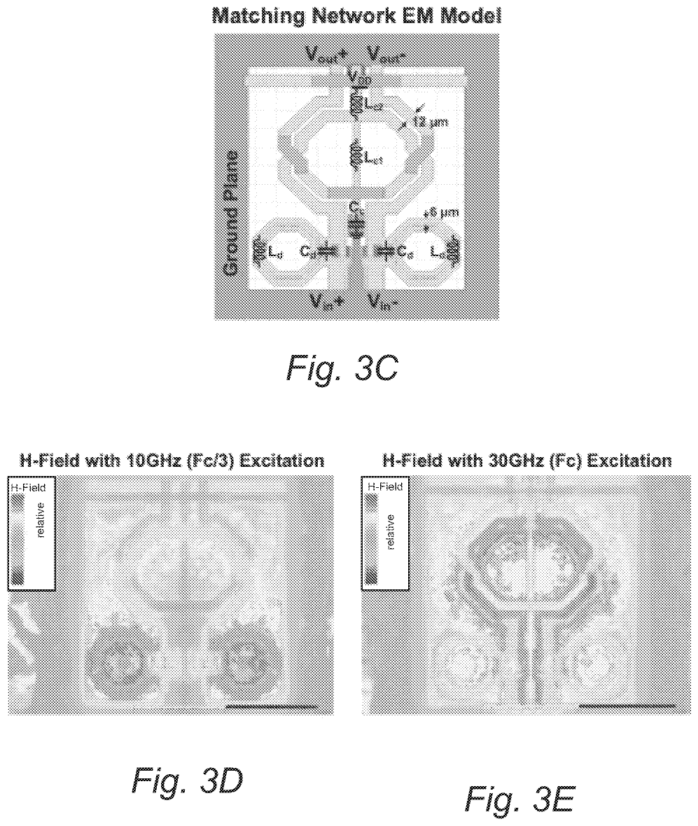

Subharmonic switching power amplifier architecture 10 can further include concurrent harmonic and subharmonic tuning matching network 16 which is in electrical communication with power amplifier core 12. (see, FIG. 3). Matching network 16 receives the output signal from power amplifier core 12. In a refinement, concurrent harmonic and subharmonic tuning matching network 16 is an on-chip concurrent harmonic and subharmonic tuning matching network. Matching network 16 simultaneously provides optimal impedance of the fundamental (Fc), 2^{nd} harmonic (2Fc), subharmonic (Fc/3), and 2^{nd} harmonic of subharmonic (2Fc/3) with a compact footprint without involving any tunable switches and elements. In a refinement as set forth below in more detail, matching network 16 includes a subharmonic trap in electrical communication with the at least one power amplifier. Advantageously, the subharmonic trap provides optimal load impedance at the carrier frequency and high impedance at the subharmonic frequency, reduce the area consumption of passives, and achieve common-mode rejection via magnetic field cancellation.

In a variation, subharmonic switching power amplifier architecture 10 is configured to avoid voltage reverse biasing of the power amplifier drivers for increased reliability.

In another variation, subharmonic switching power amplifier architecture 10 is configured to provide additional attenuation of the subharmonic component caused by the mismatch of phase interleaving.

In still another variation, subharmonic switching power amplifier architecture 10 is configured to provide a concurrent harmonic and subharmonic tuning class E/F2/2/3 PA for mm-wave operation.

In still another variation, subharmonic switching power amplifier architecture 10 is configured to utilize both harmonic and subharmonic tuning to reduce I/V overlap (Conduction loss) for both peak and PBO operation and allows switching PA cells to toggle at a much lower frequency in PBO.

Referring to FIG. 1, subharmonic switching power amplifier architecture 10 includes a driver stage and a pre-driver stage 20 that amplifies the input signal prior to the input signal being received by the amplifier core. In a refinement as set forth below, the pre-driver stage includes a coupled inductor-based series peaking structure to overcome bandwidth issues by enlarging the signal swing and reducing the passive area. In a refinement, the pre-driver stage includes a coupled inductor-based series peaking structure to overcome bandwidth issues by enlarging signal swing and reducing passive area. In some refinements, the coupled inductor-based peaking structure is included in wideband amplifier architectures to enlarge the signal bandwidth, enlarge signal swing, reject unwanted spectrum spurs and common-mode harmonics, and reducing chip area compared to conventional shunt and series inductive peaking structure. In a further refinement, the coupled inductor-based peaking structure is included in a transimpedance amplifier.

Referring to FIG. 1, subharmonic switching power amplifier architecture 10 also includes a wideband input transimpedance amplifier (TIA) 28 in electrical communication with input stage 30. Within input transimpedance amplifier (TIA) 28, both shunt peaking and the series peak is implemented to enhance the signal bandwidth, minimize the amplitude and phase difference at fundamental switching frequency, and subharmonic switching frequency.

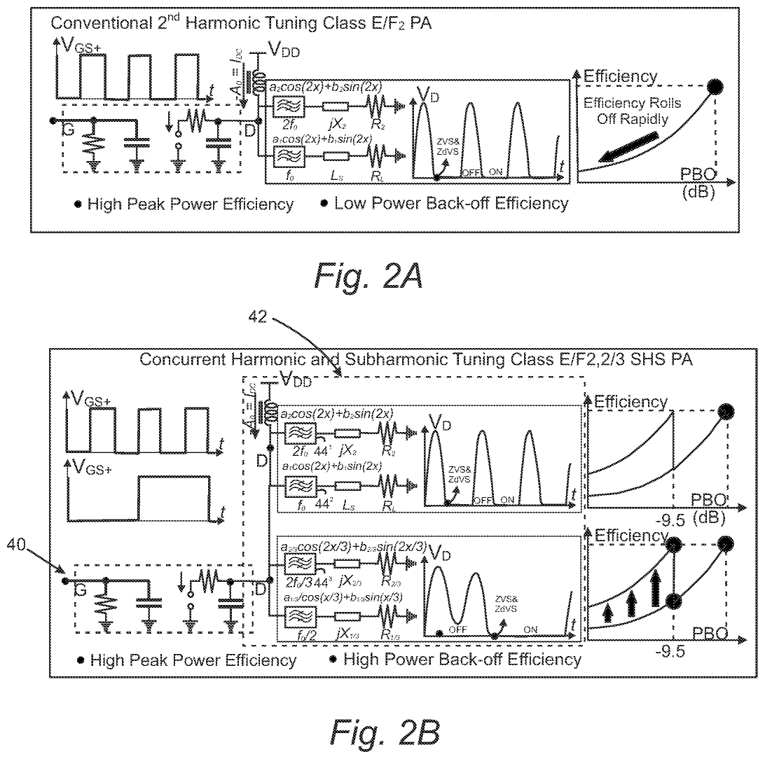

FIG. 2A provides a schematic of a conventional 2nd harmonic tuning class E/F2 power amplifier. FIG. 2B provides a schematic of the concurrent harmonic and subharmonic tuning class E/F2,2/3 SHS PA described herein. FIG. 2B shows a Class E/F2,2/3 SHS PA architecture that combines three key elements, namely, SHS, subharmonic tuning technique, and harmonic tuning based on a Class E/F PA architecture. Compared with Class E power amplifier, Class E/F2 power amplifier enhances the peak power efficiency by employing high impedance termination at the 2Fc to reduce I/V overlap in the conduction region while still maintaining the ZVS and ZdVS conditions.

In a variation, the harmonic tuning concept is extended and combined with SHS operation. First, SHS is applied to the Class E/F PA drivers, such that the drivers can toggle at a much lower frequency (only one-third of the carrier frequency) in the PBO regime. Second, 2Fc/3 tuning is introduced to form a Class E/F2/3-based output matching network, in addition to ZVS and ZdVS, during PBO operation, analogous to the operation principle of Class E/F2. As a result, the overall SHS Class E/F2,2/3 PA structure not only leverages 2Fc tuning to improve the peak power efficiency, but also establishes appropriate terminations at Fc/3 and 2Fc/3, thereby purposefully improving PBO efficiency at the same time.

Referring to FIG. 2B, switch amplifier stage 40 provide a signal to load stage 42. The load stage includes a plurality of filters 44ⁱ, where i is an integer label. The matching networks described herein can incorporate the attributes of the filters or the matching networks can be the filters. Each of the plurality of filters 44ⁱ is tuned one of the carrier frequency, a harmonic frequency, or a subharmonic frequency as described herein. In the example of FIG. 2B, load stage 42 includes filter 44¹ tuned to the second harmonic, 44² tuned to the carrier frequency, 44³ tuned to the subharmonic with frequency 2Fc/3, and 44⁴ tuned to the subharmonic with frequency Fc/3.

FIGS. 3A, 3B, and 3C depict the operation of the harmonic and subharmonic tuning matching network that concurrently provides the desired load of harmonic and subharmonic frequencies. FIG. 3A is a schematic of a portion of concurrent harmonic and subharmonic tuning architecture with amplifier core and matching network. FIG. 3B depicts the signal-dependent operation of the component of the matching network 16. FIG. 3C is a top view of the matching network.

Concurrent harmonic and subharmonic tuning architecture 10 includes amplifier core 12 that has one or more (e.g., a plurality) of switching amplifiers 14. Matching network 16 is in electrical communication with the one or more (e.g., a plurality) of switching amplifiers 14. Characteristically, matching network 16 includes at least one LC tank tuned for each of the carrier frequency, harmonic, or subharmonic being used. In a refinement, matching network 16 includes a pair of LC tanks each tuned to the same carrier frequency, harmonic, or subharmonic. A transformer couples the outputs of the LC tanks to the output. A tap (e.g., a center tap) in the transformer with an inductor in series to a capacitor can also be employed. In the example depicted in FIG. 3A, matching network 16 includes a pair of LC tanks 50, 52 that provide outputs to transformer 54 with an LC tap in the transformer. FIG. 3B depicts the signal dependent operation of the component of matching network 16.

The tuning matching network is a circuit-level enabler for Class E/F2,2/3 operation. The matching network provides optimal impedance at Fc to achieve impedance matching while simultaneously creating high impedance, as seen by common mode at 2Fc, to enable Class E/F2 operation in peak power mode. Meanwhile, high impedance can be seen by differential signals at Fc/3 and low impedance can be seen by common-mode signals at 2Fc/3, thus facilitating the subharmonic switching and tuning technique to alleviate the PBO efficiency without the need for additional tunable elements. Additionally, all of the passives are custom designed to minimize insertion loss, which finally leads to a compact footprint and renders the design conducive to mm-wave applications owing to its minimally parasitic attribute. The magnetic field of the structure with differential excitation at Fc and Fc/3 shows that the Fc/3 component is trapped inside the LC tank while the Fc component propagates to the output combiner (FIGS. 3D and 3E). In a variation, the on-chip concurrent harmonic and subharmonic tuning matching network simultaneously provides optimal impedance of the fundamental frequency (Fc) and one or more harmonic components provided by N*Fc where Nis a positive integer and/or one or more harmonic frequencies that are a fractional frequency subharmonic provided by P*Fc/M where P and M are positive frequencies. In a refinement. M is greater than P. In a refinement, The matching network provides optimal of the carrier frequency (Fc) and a component selected from the group consisting of harmonic frequencies provided by N*Fc where N is a positive integer harmonic frequencies that are a fractional frequency subharmonic provided by P*Fc/M where P and M are positive frequencies, and combinations thereof, As set forth above, the on-chip concurrent harmonic and subharmonic tuning matching network has a compact footprint without involving any tunable switches and elements.

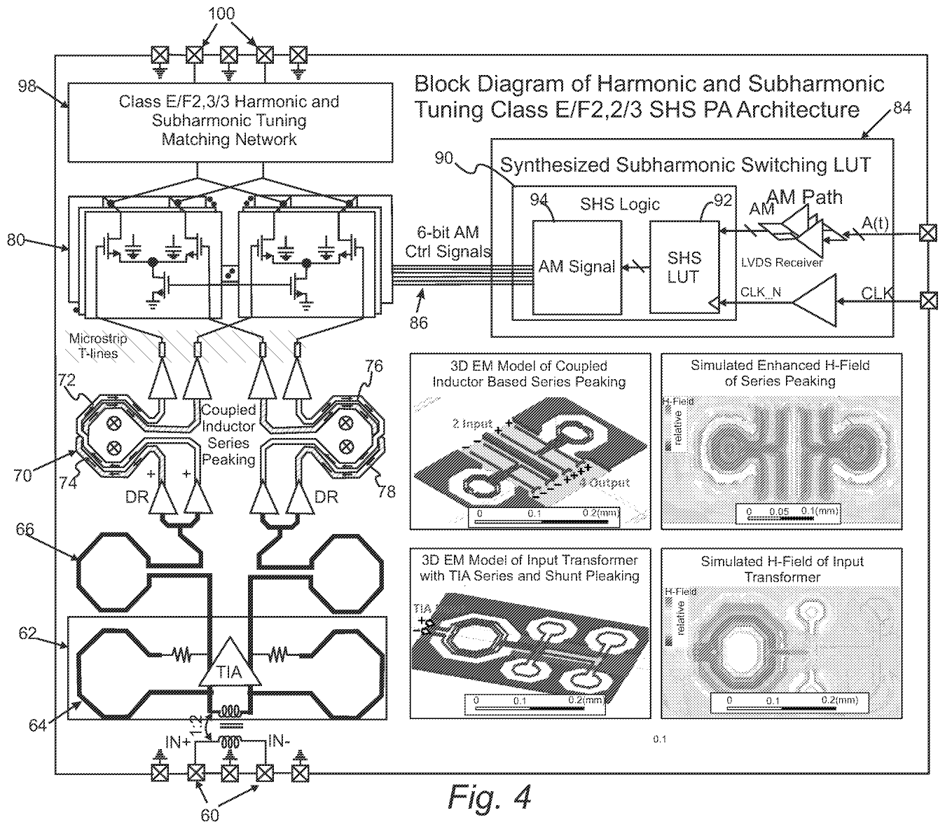

FIG. 4 shows a block diagram of the harmonic and subharmonic tuning Class E/F2.2/3 SHS power amplifier. A phase-modulated signal at either Fc or Fc/3 is first sent from inputs 60 to a wideband transimpedance amplifier (TIA) 62. Both shunt inductor(s) 64 and series inductor(s) 66 are added to further enlarge the TIA bandwidth and minimize the magnitude and phase mismatch at Fc and Fc/3. A coupled inductor-based series peaking structure 70 is embedded in the pre-driver stage to extend the bandwidth, enlarge the signal swing, and reduce the passive area. Coupled inductor-based series peaking structure 70 includes a first pair of inductors 72 and 74 and a second pair of inductors 76 and 78. The pair is for a positive signal (with respect to phase) and the second pair is for a negative signal since the currents for a positive signal and negative signal are in opposite directions. The specific design of coupled inductor-based series peaking structure 70 can achieve the same inductance with a smaller footprint since the distance that signal flow through the inductors are approximately the same. Segmented 6-bit Class E/F power amplifier arrays 80 and synthesized subharmonic switching LUT 84 that generates a SHS control table. Segmented 6-bit Class E/F power amplifier arrays 80 and synthesized subharmonic switching LUT 84 are implemented to achieve different amplitudes. The power amplifiers in power amplifier arrays 80 are activated via control lines 86 which carry control bits from the SHS control table. Therefore, output control bits depends on the input frequency. The SHS control table and therefore the control bits are generated from SHS logic 90 which includes SHS look-up-table 92 and AM signal generator 94. The control signal determines which power amplifiers are to be activated so that the signals from harmonics and subharmonics are approximately the same magnitude (i.e., same power level) as the carrier frequency signal. In general, more amplifiers need to be activated for harmonics and subharmonics. In a refinement, an amplitude control code A(t) can be imputed to set the frequency and therefore, the amplitude of the input signals. The outputs from power amplifiers in power amplifier arrays 80 are provided to matching network 98 which operates as described above. The outputs are provided from outputs 100. The 3D EM model and simulated H-field map of the passives are also provided in the lower left quadrant of FIG. 4.

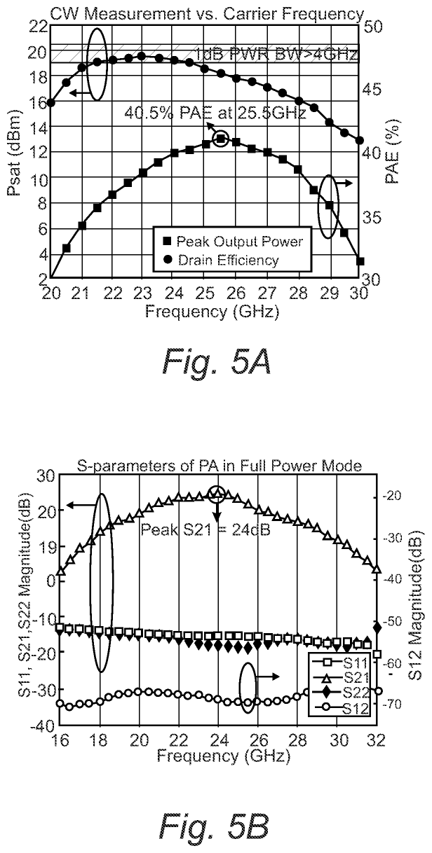

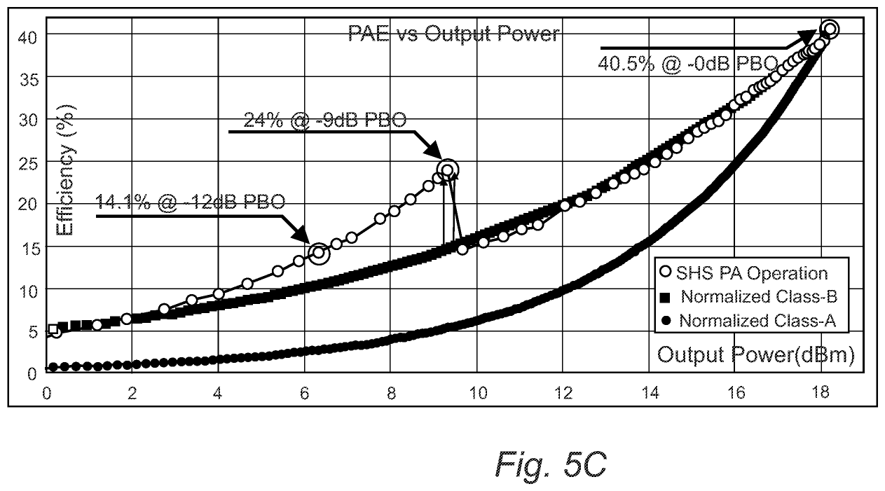

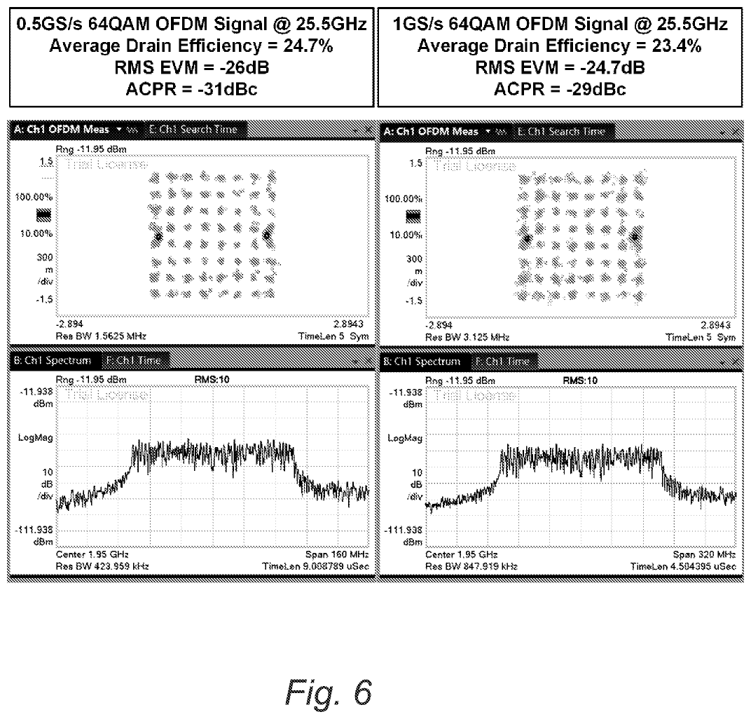

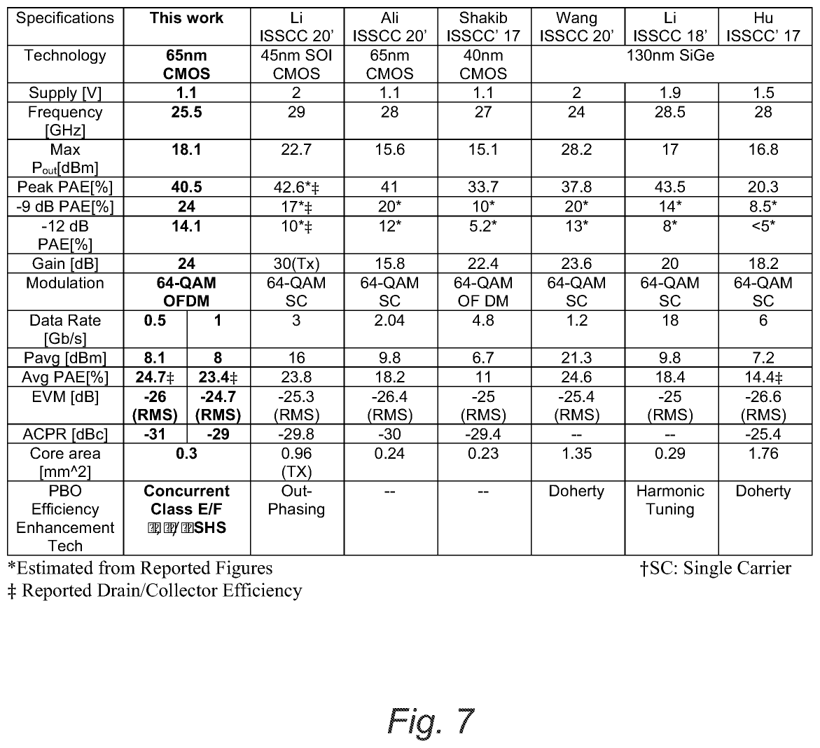

In an experimental setup, the 65 nm CMOS prototype is bonded directly to the PCB, and the input/output signal is sent to/captured from the chip via a differential probe card. FIG. 5 shows the measured small-signal S-parameters from 16 GHZ to 32 GHz. The peak S21 is 24 dB at 24 GHZ. The measured S11 is lower than −10 dB from 16 GHz to 32 GHZ. The PA achieves 40.5% PAE with 18.1 dBm Psat at 25.5 GHz with 1 dB power bandwidth over 4 GHZ. The efficiency at −9 dB PBO is 24%, which is a 4.55-fold improvement over a normalized Class A PA. FIG. 6 shows the modulation tests using OFDM 64-QAM signals with 0.5GS/s and 1GS/s data rate, respectively. It achieves −26 dB/−24.7 dB rms EVM in SHS operation mode, with an average drain efficiency of 24.7%/23.4%. The PA architecture achieves a superior deep PBO efficiency compared with state-of-the-art mm-wave CMOS and SiGe PAs [4-9], as presented in FIG. 7.

Additional details are set forth A. Zhang, M. Ayesh, S. Mahapatra and M. S.-W. Chen, “A 24-28 GHz Concurrent Harmonic and Subharmonic Tuning Class E/F2,2/3 Subharmonic Switching Power Amplifier Achieving Peak/PBO Efficiency Enhancement,” 2021 IEEE Custom Integrated Circuits Conference (CICC), 2021, pp. 1-2, doi: 10.1109/CICC51472.2021.9431547 (25-30 Apr. 2021); the entire disclosure of which is hereby incorporated by reference in its entirety.

While exemplary embodiments are described above, it is not intended that these embodiments describe all possible forms of the invention. Rather, the words used in the specification are words of description rather than limitation, and it is understood that various changes may be made without departing from the spirit and scope of the invention. Additionally, the features of various implementing embodiments may be combined to form further embodiments of the invention.

### REFERENCES

[1] A. Zhang, et al., “A Subharmonic Switching Digital Power Amplifier for Power Back-Off Efficiency Enhancement,” IEEE JSSC, vol. 54, no. 4, pp. 1017-1028, April 2019.
[2] A. Zhang, et al., “A Watt-Level Phase-Interleaved Multi-Subharmonic Switching Digital Power Amplifier,” in IEEE JSSC, vol. 54, no. 12, pp. 3452-3465, December 2019.
[3] A. Zhang, et al., “26.6 A 5-to-6 GHz Current-Mode Subharmonic Switching Digital Power Amplifier for Enhancing Power Back-Off Efficiency,” ISSCC, pp. 364-366, 2021.
[4] S. Li, et al., “A 28 GHz Current-Mode Inverse-Outphasing Transmitter Achieving 40%/31% PA Efficiency at Psat/6 dB PBO and Supporting 15 Gbit/s 64-QAM for 5G Communication,” ISSCC, pp. 366-368, 2020.
[5] S. N. Ali, et al., “A 28 GHz 41%-PAE linear CMOS power amplifier using a transformer-based AM-PM distortion-correction technique for 5G phased arrays,” ISSCC, pp. 406-408, 2018.
[6] S. Shakib, et al., “2.7 A wideband 28 GHz power amplifier supporting 8×100 MHz carrier aggregation for 5G in 40 nm CMOS,” ISSCC, pp. 44-45, 2017.
[7] F. Wang, et al., “A 24-to-30 GHz Watt-Level Broadband Linear Doherty Power Amplifier with Multi-Primary Distributed-Active-Transformer Power-Combining Supporting 5G NR FR2 64-QAM with >19 dBm Average Pout and >19% Average PAE,” ISSCC, pp. 362-364, 2020.
[8] T. Li, et al., “A continuous-mode harmonically tuned 19-to-29.5 GHz ultra-linear PA supporting 18 Gb/s at 18.4% modulation PAE and 43.5% peak PAE,” ISSCC, pp. 410-412, 2018.
[9] S. Hu, et al., “2.1 A 28 GHz/37 GHz/39 GHz multiband linear Doherty power amplifier for 5G massive MIMO applications,” ISSCC, 2017, pp. 32-33, 2017.
[10] A. Zhang, et al., “A 24-28 GHz Concurrent Harmonic and Subharmonic Tuning Class E/F2,2/3 Subharmonic Switching Power Amplifier Achieving Peak/PBO Efficiency Enhancement,” CICC, April 2021.

What is claimed is:

1. A subharmonic switching power amplifier architecture comprising:
a power amplifier core that includes at least one power amplifier that receives an input signal and is operable in a power back-off region,
wherein the at least one power amplifier is configured to be toggled at a carrier frequency (Fc) when a power level of the input signal is equal to or higher than a predetermined power level and at a subharmonic component of the carrier frequency when the power level of the input signal is less than the predetermined power level, the power amplifier being configured to be a Class-D power amplifier or a current mode Class-D power amplifier or a Class-E power amplifier or a Class-E/F power amplifier.

2. The subharmonic switching power amplifier architecture of claim 1 configured to reduce conduction loss and minimize output impedance variation by toggling a plurality of power amplifier branches.

3. The subharmonic switching power amplifier architecture of claim 1 further comprising an on-chip concurrent harmonic and subharmonic tuning matching network that receives an output signal from the power amplifier core.

4. The subharmonic switching power amplifier architecture of claim 3 wherein the on-chip concurrent harmonic and subharmonic tuning matching network simultaneously provide optimal impedance of the carrier frequency (Fc) and one or more harmonic components provided by N*Fc where N is a positive integer and/or one or more harmonic frequencies that are a fractional frequency subharmonic provided by P*Fc/M where P and M are positive frequencies, the on-chip concurrent harmonic and subharmonic tuning matching network having a compact footprint without involving any tunable switches and elements.

5. The subharmonic switching power amplifier architecture of claim 4 wherein the on-chip concurrent harmonic and subharmonic tuning matching network includes a subharmonic trap in electrical communication with the at least one power amplifier.

6. The subharmonic switching power amplifier architecture of claim 5 wherein the subharmonic trap provides optimal load impedance at the carrier frequency and high impedance at a subharmonic frequency reduces area consumption of passives, and achieves common-mode rejection via magnetic field cancellation.

7. The subharmonic switching power amplifier architecture of claim 1 configured to avoid voltage reverse biasing of power amplifier drivers for increased reliability.

8. The subharmonic switching power amplifier architecture of claim 1 configured to provide additional attenuation of the subharmonic component caused by a mismatch of phase interleaving.

9. The subharmonic switching power amplifier architecture of claim 1 configured to provide a concurrent harmonic and subharmonic tuning class E/F2/2/3 PA for mm-wave operation.

10. The subharmonic switching power amplifier architecture of claim 1 configured to utilize both harmonic and subharmonic tuning to reduce I/V overlap (Conduction loss) for both peak and PBO operation and allows switching PA cells to toggle at a much lower frequency in PBO.

11. The subharmonic switching power amplifier architecture of claim 1 further comprising a driver stage and a pre-driver stage that amplifies the input signal prior to the input signal being received by the power amplifier core.

12. The subharmonic switching power amplifier architecture of claim 11 wherein the pre-driver stage includes a coupled inductor-based series peaking structure to overcome bandwidth issues by enlarging signal swing and reducing passive area.

13. The subharmonic switching power amplifier architecture of claim 12, wherein the coupled inductor-based peaking structure is included in wideband amplifier architectures to enlarge signal bandwidth, enlarge signal swing, reject unwanted spectrum spurs and common-mode harmonics, and reducing chip area compared to conventional shunt and series inductive peaking structure.

14. The subharmonic switching power amplifier architecture of claim 13, wherein the coupled inductor-based peaking structure is included in a transimpedance amplifier.

15. The subharmonic switching power amplifier architecture of claim 13 further comprising a wideband input transimpedance amplifier (TIA) in which both shunt peaking and series peak is implemented to enhance signal bandwidth, minimize amplitude and phase difference at fundamental switching frequency, and subharmonic switching frequency.

16. The subharmonic switching power amplifier architecture of claim 1 configured to operate from RF to mm-Wave frequencies.

17. The subharmonic switching power amplifier architecture of claim 1 configured to operate at frequencies from 0.1 to 60 GHz.

18. An on-chip concurrent tuning matching network comprising:
a subharmonic trap, the on-chip concurrent tuning matching network configured to simultaneously provide optimal impedance at a carrier frequency (Fc) and one or more harmonics and/or one or more subharmonics.

19. The on-chip concurrent tuning matching network of claim 18 configured to simultaneously provide optimal impedance of the carrier frequency (Fc) and a component selected from the group consisting of harmonic frequencies provided by N*Fc where N is a positive integer harmonic frequencies that are a fractional frequency subharmonic provided by P*Fc/M where P and M are positive frequencies, and combinations thereof, the on-chip concurrent tuning matching network having a compact footprint without involving any tunable switches and elements.

20. The on-chip concurrent tuning matching network of claim 18 wherein the subharmonic trap is a coupled-inductor-based subharmonic trap.
